(19) United States
(12) Patent Application Publication
(10) Pub. No.: US 2007/0128465 A1
(43) Pub. Date: Jun. 7, 2007

(54) Transparent electrode for organic electronic devices

(75) Inventors: Jie Liu, Niskayuna, NY (US); James Anthony Cella, Clifton Park, NY (US); Min Yan, Ballston Lake, NY (US); Anil Raj Duggal, Niskayuna, NY (US); Gautam Parthasarathy, Saratoga Springs, NY (US); Svetlana Rogojevic, Niskayuna, NY (US); Michael Scott Herzog, Voorheesville, NY (US)

Correspondence Address: Andrew J. Caruso;General Electric Global Research, Docket Room K1-4A59, One Research Circle, Niskayuna, NY, 12309, US

(73) Assignee: General Electric Company, Schenectady, NY (US)

(21) Appl. No.: 11/295,768

(22) Filed: Dec. 5, 2005

(51) Int. Cl. B32B 9/00; H01B 5/00; H01L 51/50

(52) U.S. Cl. 428/689; 428/523; 428/702; 428/917; 313/503; 313/506; 257/E51.019; 427/58; 427/108

(57) ABSTRACT

Described herein is a transparent electrode comprising at least one optically transparent electrically conductive layer; and at least one optically transparent intermediate layer, wherein said optically transparent conductive layer is in contact with said optically intermediate layer, and wherein said optically transparent conductive layer and said optically transparent intermediate layer together transmit at least 50 percent of incident light having a wavelength in a range between about 200 and about 1200 nanometers, said optically transparent conductive layer having a bulk conductivity at least 100 Siemens per centimeter (S/cm), said optically transparent intermediate layer being comprised of a material having a bulk electrical conductivity at room temperature less than 10⁻¹² Siemens per centimeter and a band gap of 3.5 eV. Described herein are also methods for forming a transparent electrode, and transparent electronic devices comprising at least one transparent electrode.

### BACKGROUND

The invention relates generally to transparent electrodes comprising at least one conductive layer in contact with an intermediate layer, and electronic devices produced from the transparent electrodes.

Organic light-emitting devices (OLEDs) are of significant interest due to their current application in displays and their potential application in general lighting. Typically OLEDs are constructed with a “bottom-emitting” configuration where active organic layers are deposited on top of a transparent indium tin oxide (ITO) contact and then capped with a non-transparent low function metal cathode, such as Ca/Al and NaF/Al. With such a design, the ITO operates as the anode because its work function is closer to the highest occupied molecular orbital (HOMO) of organic emissive materials than to the lowest unoccupied molecular orbital (LUMO). Recently there has been increasing interest in the fabrication of OLEDs that are capable of emitting light either from the top surface (top-emitting or surface-emitting) or from both the bottom and top surface (transparent OLEDs, referred to as TOLEDs). ; The development of the top-emitting architecture is motivated by the need to integrate OLED displays with existing inorganic-based chip technologies where all drive electronics (such as thin film transistors) are constructed on non-transparent substrates. TOLEDs are attractive for a number of reasons. For example, TOLED technology enables some specialty applications such as heads-up displays and see-through signage that are difficult to achieve with other existing technologies. In addition, TOLED technology also allows new device architectures such as stacked and tandem devices consisting of multiple OLED elements that are stacked vertically. Those stacked OLEDs with appropriately tailored individual elements (for instance, using red, green and blue elements) hold potential in the development of high efficiency, long lived devices, full-color high resolution flat-panel displays, and/or color-tunable light-sources.

Several obstacles exist which impede the development of TOLED technology. First, there is a need to provide new alternative device architectures which provide efficient TOLEDs. In addition, there is a need for materials and methods which will provide low cost access to TOLEDs.

### BRIEF DESCRIPTION

In one embodiment, the invention provides a transparent electrode comprising:

(a) at least one optically transparent electrically conductive layer; and

(b) at least one optically transparent intermediate layer having a thickness of from about 1 and about 100 angstroms;

wherein said optically transparent electrically conductive layer is in contact with said optically transparent intermediate layer, said optically transparent conductive layer having a conductivity at least 100 Siemens per centimeter (S/cm), said optically transparent intermediate layer being comprised of a material having a bulk electrical conductivity at room temperature of less than about 10⁻¹² Siemens per centimeter, and a band gap of at least 3.5 eV.

In another embodiment, the invention provides a light emitting device comprising:

(a) at least one optically transparent electrically conductive layer

(b) at least one optically transparent intermediate layer having a thickness of from about 1 and about 100 angstroms; and

(c) at least one electro-active organic layerwherein said optically transparent electrically conductive layer is in contact with said optically transparent intermediate layer, said optically transparent conductive layer having a conductivity at least 100 Siemens per centimeter (S/cm), said optically transparent intermediate layer being comprised of a material having a bulk electrical conductivity at room temperature of less than about 10⁻¹² Siemens per centimeter, and a band gap of at least 3.5 eV.

In yet another embodiment, the invention provides a method for fabricating a transparent electronic device, the method comprising:

providing a substrate;

disposing a transparent electrically conducting layer having a conductivity at least 100 Siemens per centimeter (S/cm); and

disposing a transparent intermediate layer having a thickness of from about 1 and about 100 angstroms, a bulk electrical conductivity at room temperature of less than about 10⁻¹² Siemens per centimeter (S/cm), and a band gap of at least 3.5 eV;
wherein the transparent intermediate layer comprises sodium fluoride, calcium oxide, an amine-substituted polymeric material having a repeat unit as shown in structure (I): 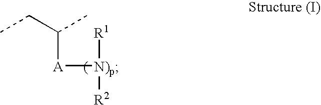
wherein A comprises an aromatic radical, R¹ and R² comprise independently of each other hydrogen atom, C₁-C₃₀ aliphatic radicals, C₃-C₃₀ cycloaliphatic groups, C₃-C₃₀ aromatic radicals, or any combination thereof; and “p” comprises an integer from 1 to the maximum number of positions available for substitution on A.

### DRAWINGS

These and other features, aspects, and advantages of the present invention will become better understood when the following detailed description is read with reference to the accompanying drawings in which like characters represent like parts throughout the drawings, wherein:

FIG. 1 illustrates a side view of an exemplary electronic device arrangement.

FIG. 2 illustrates a side view of another exemplary electronic device arrangement.

FIG. 3 illustrates a side view of an exemplary stacked/tandem electronic device arrangement.

FIG. 4 illustrates a side view of an exemplary variation of the stacked/tandem electronic device arrangement shown in FIG. 3.

FIG. 5 illustrates a further embodiment of an exemplary arrangement of an electronic device.

FIG. 6 illustrates yet another embodiment of an exemplary arrangement of an electronic device.

FIG. 7 shows the illustrative method steps to form an exemplary electronic device arrangement.

FIG. 8 shows the illustrative method steps to form another exemplary configuration of electronic device arrangement.

FIG. 9 shows the optical transmittance as a function of wavelength of the transparent OLED with a bare ITO cathode made by the method described in comparative example 2.

FIG. 10 shows the efficiency as a function of current density characteristics of the transparent OLED with a bare ITO cathode made by the method described in comparative example 2.

FIG. 11 shows the optical transmittance as a function of wavelength of the transparent OLED with a PS-Amine/ ITO bilayer cathode made by the method described in example 3.

FIG. 12 shows the efficiency as a function of current density characteristics of the transparent OLED with a PS-Amine/ITO bilayer cathode made by the method described in example 3.

FIG. 13 shows the optical transmittance as a function of wavelength of the transparent OLED with a NaF/ ITO bilayer cathode made by the method described in example 4.

FIG. 14 shows the efficiency as a function of current density characteristics of the transparent OLED with a NaF/ITO bilayer cathode made by the method described in example 4.

### DETAILED DESCRIPTION

The present invention may be understood more readily by reference to the following detailed description of preferred embodiments of the invention and the examples included therein. In the following specification and the claims which follow, reference will be made to a number of terms which shall be defined to have the following meanings:

The singular forms “a”, “an” and “the” include plural referents unless the context clearly dictates otherwise.

“Optional” or “optionally” means that the subsequently described event or circumstance may or may not occur, and that the description includes instances where the event occurs and instances where it does not.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e. —OPhC(CF₃)₂PhO—), 4-chloromethylphen-1-yl, 3-trifluorovinyl-2-thienyl, 3-trichloromethylphen-1-yl (i.e. 3-CCl₃Ph-), 4-(3-bromoprop-1-yl)phen-1-yl (i.e. 4-BrCH₂CH₂CH₂Ph-), and the like. Further examples of aromatic radicals include 4-allyloxyphen-1-oxy, 4-aminophen-1-yl (i.e. 4—H₂NPh-), 3-aminocarbonylphen-1-yl (i.e. NH₂COPh-), 4-benzoylphen-1-yI, dicyanomethylidenebis(4-phen-1-yloxy) (i.e. —OPhC(CN)₂PhO-), 3-methylphen-1-yl, methylenebis(4-phen-1-yloxy) (i.e. —OPhCH₂PhO-), 2-ethylphen-1-yl, phenylethenyl, 3-formyl-2-thienyl, 2-hexyl-5-furanyl, hexamethylene-1,6-bis(4-phen-1-yloxy) (i.e. —OPh(CH₂)₆PhO-), 4-hydroxymethylphen-1-yl (i.e. 4-HOCH₂Ph-), 4-mercaptomethylphen-1-yl (i.e. 4-HSCH₂Ph-), 4-methylthiophen-1-yl (i.e. 4-CH₃SPh-), 3-methoxyphen-1-yl, 2-methoxycarbonylphen-1yloxy (e.g. methyl salicyl), 2-nitromethylphen-1-yl (i.e. 2-NO₂CH₂Ph), 3-trimethylsilylphen-1-yl, 4-t-butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₈—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is a cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis (cyclohex-4-yl) (i.e. —C₆H₁₀C(CF₃)₂C₆H₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀—), and the like. Further examples of cycloaliphatic radicals include 4-allyloxycyclohex-1-yl, 4-aminocyclohex-1-yl (i.e. H₂NC₆H₁₀—), 4-aminocarbonylcyclopent-1-yl (i.e. NH₂COC₅H₈—), 4-acetyloxycyclohex-1-yl, 2,2-dicyanoisopropylidenebis(cyclohex-4-yloxy) (i.e. —OC₆H₁₀C(CN)₂C₆H₁₀O—), 3-methylcyclohex-1-yl, methylenebis(cyclohex-4-yloxy) (i.e. —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e. —OC₆H₁₀(CH₂)₆C₆H₁₀O—), 4- hydroxymethylcyclohex-1-yl (i.e. 4-HOCH₂C₆H₁₀—), 4-mercaptomethylcyclohex-1-yl (i.e. 4-HSCH₂C₆H₁₀—), 4-methylthiocyclohex-1-yl (i.e. 4-CH₃SC₆H₁₀—), 4methoxycyclohex-1-yl, 2-methoxycarbonylcyclohex-1-yloxy (2-CH₃OCOC₆H₁₀O—), 4-nitromethylcyclohex-1-yl (i.e. NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, haloalkyl groups , conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g. —CH₂CHBrCH₂—), and the like. Further examples of aliphatic radicals include allyl, aminocarbonyl (i.e. —CONH₂), carbonyl, 2,2-dicyanoisopropylidene (i.e. —CH₂C(CN)₂CH₂—), methyl (i.e. —CH₃), methylene (i.e. —CH₂—), ethyl, ethylene, formyl (i.e. —CHO), hexyl, hexamethylene, hydroxymethyl (i.e. —CH₂OH), mercaptomethyl (i.e. —CH₂SH), methylthio (i.e. —SCH₃), methylthiomethyl (i.e. —CH₂SCH₃), methoxy, methoxycarbonyl (i.e. CH₃OCO—) , nitromethyl (i.e. —CH₂NO₂), thiocarbonyl, trimethylsilyl ( i.e. (CH₃)₃Si—), t-butyldimethylsilyl, 3-trimethyoxysilypropyl (i.e. (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e. CH₃—) is an example of a C₁ aliphatic radical. A decyl group (i.e. CH₃(CH2)₉—) is an example of a C₁₀ aliphatic radical.

As noted, the present invention provides a transparent electrode comprising at least one optically transparent electrically conductive layer; and at least one optically transparent intermediate layer having a thickness of from about 1 and about 100 angstroms. The optically transparent electrically conductive layer may be in contact with the optically transparent intermediate layer, and the optically transparent conductive layer has a conductivity at least 100 Siemens per centimeter (S/cm), while the optically transparent intermediate layer comprises a material having a bulk electrical conductivity at room temperature of less than about 10⁻¹² Siemens per centimeter, and a band gap of at least 3.5 eV. Also, as previously noted, the invention provides a light emitting device that comprises a transparent electrode comprising at least one optically transparent electrically conducting layer; and at least one optically transparent intermediate layer having a thickness of from about 1 and about 100 angstroms.

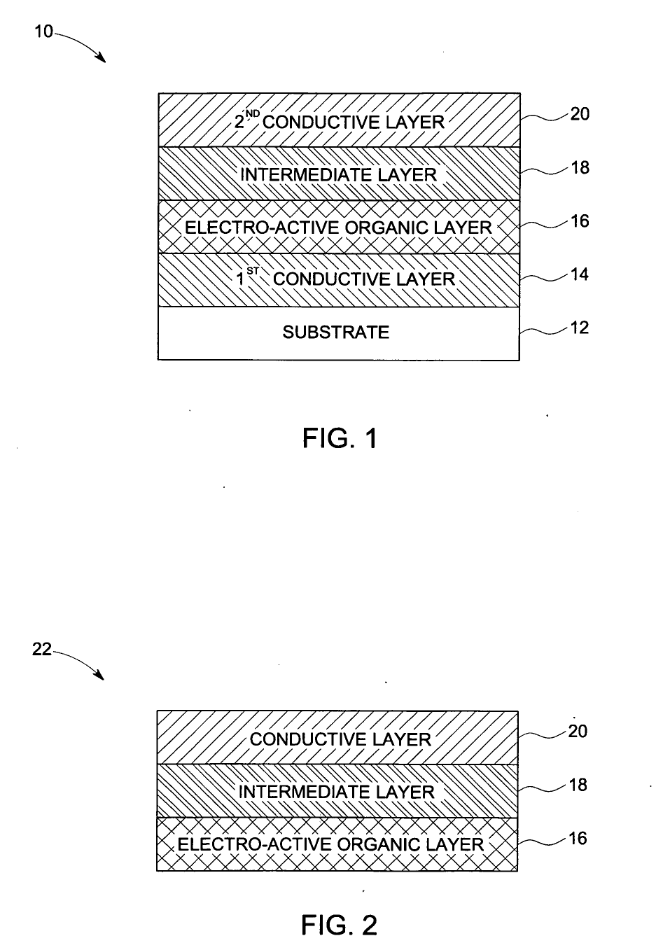

Referring to the drawings, FIG. 1 illustrates a side view of an exemplary electronic device arrangement 10. It is to be understood that the schematic shown here is not to scale. The electronic device 10 comprises a substrate 12. The substrate may comprise a metal, a coated metal, a planarized metal, glass, a plastic material, a coated plastic material, a thermoplastic material, a thermoset material, an elastomeric material, or any combinations thereof. The substrate is in contact with a first conductive layer 14. The first conductive layer may comprise at least one zero-valent metal (such as Al, Ag, Au, and the like), or the first conductive layer may comprise at least one metal oxide (such as indium tin oxide, tin oxide, indium zinc oxide, etc), or the first conductive layer may comprise at least one conductive organic material (such as PEDOT:PSS), or the the first conductive layer may comprise two or more of the foregoing in any combination, for example, the case in which the first conductive layer comprises two zero valent metals, and three conductive organic materials but does not include a metal oxide In still yet another embodiment, the first conductive layer comprises at least two metal oxides, and two conductive organic materials but does not include a zero valent metal. Alteratively, the first conductive layer may comprise each of at least one zero valent metal, at least one metal oxide, and at least one conductive organic material in any combination The first conductive layer is in contact with an electro-active organic layer 16. It should be noted that there could be one or more such electro-active organic layers. The electro-active organic layer is in contact with an intermediate layer 18. The intermediate layer may be made of organic material, or inorganic material. When the intermediate layer is an organic material, it may be a polymeric material, or a small molecule compound. The second conductive layer 20 is in contact with the intermediate layer 18. The second conductive layer may be made of the same material as the first conductive layer, or may be made of a different material. Typically, a requisite amount of voltage is applied between the first conductive layer and the second conductive layer to operate the device.

Various configurations may be implemented by constructing stacked devices having more than one intermediate layers, more than one electro-active layers, more than one conductive layers, and so forth, in combinations with other layers. In general, with an appropriate combination of the various layers, the electronic device either shows enhanced performance or meets specifications for various applications. FIG. 2 illustrates a side view of an electronic device in another embodiment of the invention. The electronic device arrangement 22 comprises at least one electro-active organic layer 16. The electro-active organic layer 16 is in contact with the intermediate layer 18. The intermediate layer 18 is in contact with a conductive layer 20.

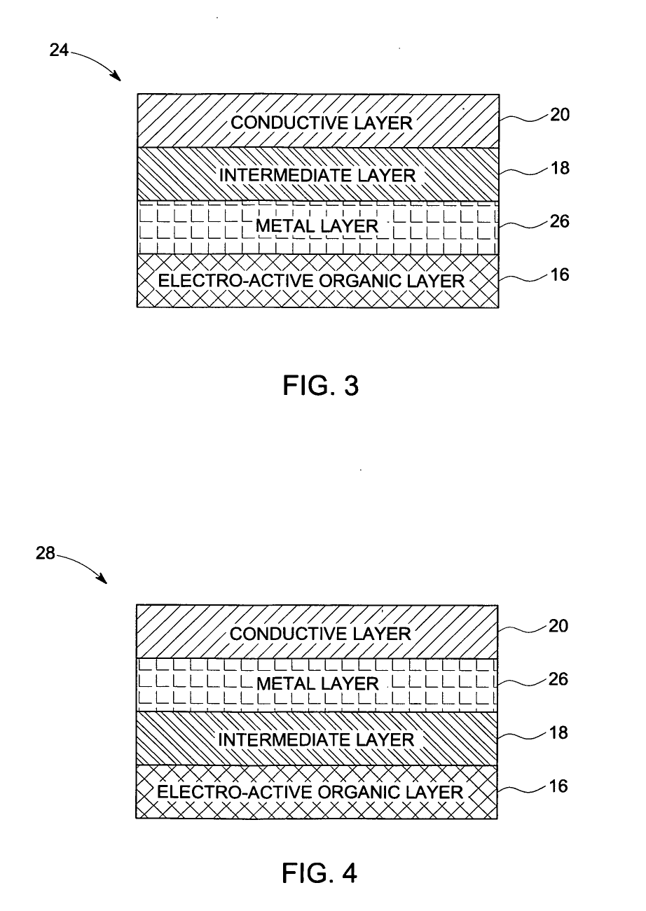

Still further examples and varieties of stacked electronic devices that use the transparent electrodes comprises at least one metal layer, at least one charge transport layer, at least one charge injection layer, or combinations thereof as additional layers. FIG. 3 illustrates one embodiment of a stacked/tandem device 24, which comprises an electro-active organic layer 16, a metal layer 26, an intermediate layer 18, and a conducting layer 20. FIG. 4 illustrates a further embodiment of the invention wherein a variation of the configuration described in FIG. 3 is given. An electronic device 28 comprises an electro-active organic layer 16 that is in contact with an intermediate layer 18, which in turn is in contact with a metal layer 26, which is finally coated with a conductive layer 20. It should be noted that the metal layer 26 in combination with the conductive layer 20 functions as the conductive layer. Thus, the intermediate layer 20 is in contact with the metal layer 26 part of the conductive layer 20.

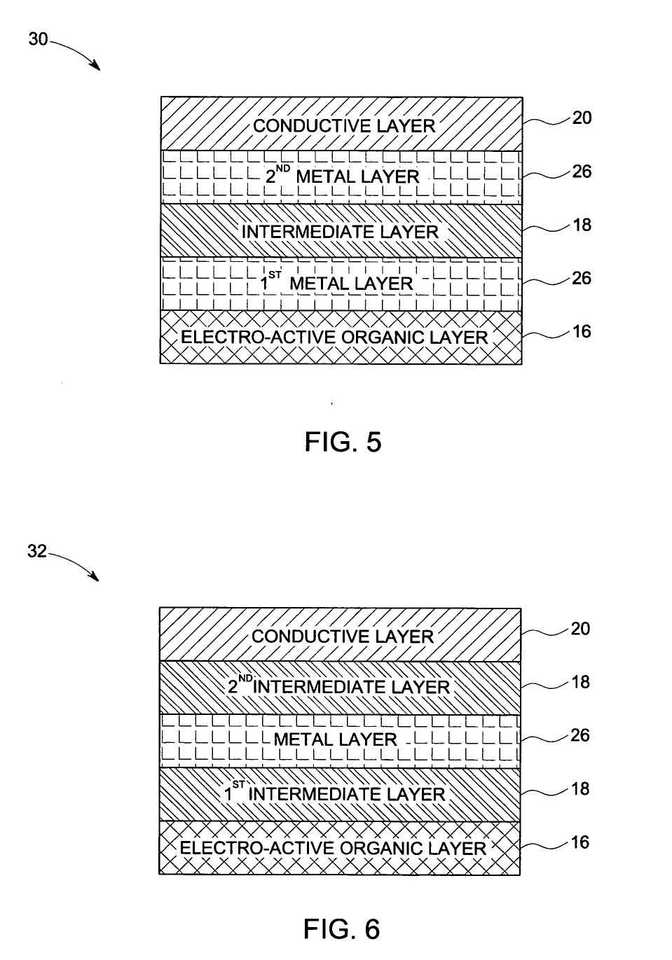

FIG. 5 illustrates another configuration of an electronic device 30 as a further embodiment of the invention. An electro-active organic layer 16 is in contact with a first metal layer 26. The first metal layer is in contact with an intermediate layer 18 that is then in contact with a second metal layer 26 such that the intermediate layer is sandwiched between the two metal layers. The first metal layer and the second metal layer may be made of the same metal or of different metals in the device. Finally, the second metal layer is in contact with a conductive layer 20. Thus, the intermediate layer is in contact with the metal layer 26 part of the conductive layer 20.

FIG. 6 illustrates yet another configuration of an electronic device 32 as yet another aspect of the invention. An electro-active organic layer 16 is in contact with a first intermediate layer 18. The first intermediate layer is in contact with a metal layer 26, which is in turn in contact with a second intermediate layer 18, such that the metal layer 26 is sandwiched between the two intermediate layers. Finally, the second intermediate layer is in contact with a conductive layer 20.

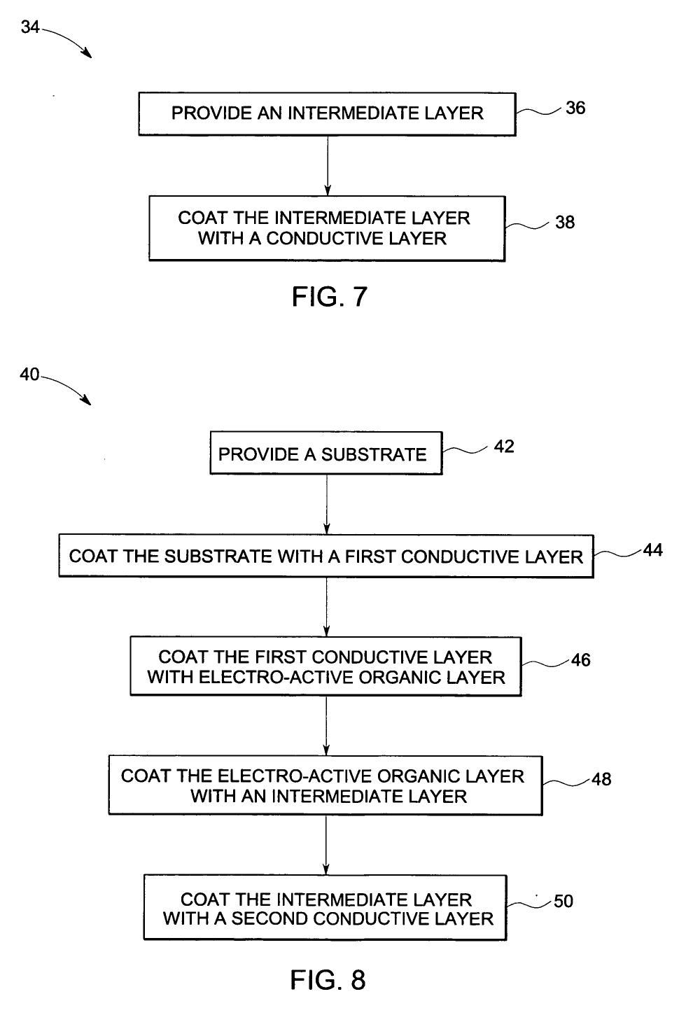

FIG. 7 illustrates method steps 34 followed to form an electronic device. The first step 36 includes providing an intermediate layer. The intermediate layer is then coated with a conductive layer, as designated by numeral 38. The coating may be achieved by techniques known to those skilled in the art, such as thermal evaporation, sputtering, and the like.

FIG. 8 illustrates the method steps 40 followed to form an electronic device with a different configuration. The first step 42 includes providing a substrate. The substrate is coated with a first conductive layer, as depicted in the figure by numeral 44. The first conductive layer is then coated with at least one electro-active organic layer, as shown in step 46. The electro-active organic layer is then coated with an intermediate layer, as designated by 48. The intermediate layer is then coated with a second conductive layer, as shown in step 50. The coating in each step may be achieved by following the same technique or a different technique in each step. The coating method followed will depend on the materials chosen and the final device being prepared, and will be apparent to those skilled in the art.

One aspect of the present invention is an optically transparent electrode, which is included in an electronic device. The electrode comprises optically transparent electrically conductive layer and an intermediate layer in contact with the transparent electrically conductive layer. The intermediate layer is made of an organic material, an inorganic material, or combinations thereof. In one embodiment, the intermediate layer is an inorganic material selected from the group consisting of metal halides such as sodium fluoride, lithium fluoride, barium fluoride, sodium chloride, and metal oxides such as calcium oxide, barium oxide and the like, and combinations thereof. When the intermediate layer is an organic material, it may be made of polymeric material or non-polymeric material. Suitable polymeric materials that may be used as intermediate layer include, for example, a poly(alpha-olefin), a poly(alkenylaromatic), a polyphenylene, a polyfluorene, a polycarbonate, a polyimide, a polyester, a copolymer of two or more of the foregoing, blends thereof. By “copolymer of two or more of the foregoing” is meant that the structural units found in the copolymer comprise structural units from each of the individual polymers referenced. The optically transparent conductive layer comprises at least one conductive material. Suitable conductive materials which may be employed include, for example, zero valent metals (such as Al, Ag, Au, and the like.), metal oxide containing materials (such as indium tin oxide, tin oxide, indium zinc oxide, and the like), and conductive organic materials (such as PEDOT:PSS), or any combinations thereof.

In one embodiment, intermediate layer comprises at least one amine-substituted polymeric material, at least one amine-substituted non-polymeric material, or combinations thereof. The amine-substituted polymeric material may be a homopolymer, copolymer (random or block copolymer), or any combinations thereof. In an embodiment, the amine-substituted polymeric material may have at least one amine group. Further, the amine group may be present either in the repeat units of the polymeric material, and/or the terminal group(s) of the polymeric material. Non-polymeric materials having amine substituent(s) advantageously include materials having an adequately high molecular weight and a sufficiently low volatility so as to permit their use in producing electronic devices.

As used herein, the amine substituent is meant to include a primary, secondary, or a tertiary amine. Secondary amine substituents have a general formula NHR¹, wherein R¹ is a C₁-C₃₀ aliphatic radical, C₃-C₃₀ aromatic radical, or a C₃-C₃₀ cycloaliphatic radical. Tertiary amine substituents have a general formula NR¹R², where R¹ and R² are independently a C₁- C₃₀ aliphatic radical, a C₃-C₃₀ aromatic radical, or a C₃-C₃₀ cycloaliphatic radical.

In another embodiment, the amine-substituted polymeric material includes a repeat unit having a structure (I) listed below. 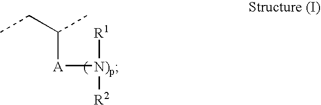
wherein A is an aromatic radical, R¹ and R² are independently a hydrogen , a C₁-C₃₀ aliphatic radical, a C₃-C₃₀ cycloaliphatic radical, a C₃-C₃₀ aromatic radical; and “p” is an integer from 1 to the maximum number of positions available for substitution on A. The dashed line (----) signals the point of attachment to an adjacent repeat unit within the polymer.

In an embodiment, the NR¹R² group may be one of dialkylamino, monoalkylamino, NH₂ groups, or any combinations thereof; and A is a phenylene group. In yet another embodiment, when NR¹R² group is one of dialkylamino group, monoalkylamino, NH₂ groups, or any combinations thereof, and A is a benzylene group. Suitable radicals represented by structure I are illustrated by Examples I-1 through I-10 in Table 1. For instance, in Example I-1 of Table 1, R¹ and R² represent structure I wherein the nitrogen is unsubstituted, the group A is a phenyl radical, and the value of “p” is 1. The dashed line (----) signals the point of attachment of the nitrogen atom to the aromatic radical, while the * indicates the point of attachment of the A radical to the carbon atom of the repeat unit. Similarly, I-2 represents the situation wherein R¹ and R² represent structure I wherein the nitrogen is substituted with a monoalkyl group, the group A is a phenyl radical, and the value of “p” is 1. Further, in table 1, examples I-3, I-4, I-5, I-9 and I-10 are situations wherein the nitrogen atom is disubstituted with aliphatic radical; I-6 is the situation wherein the nitrogen atom is disubstituted with cycloaliphatic radicals; and I-7 and I-8 are situations wherein the nitrogen atom is disubstituted with aromatic radicals. Also, examples I-8, I-9 and I-10 are cases wherein the aromatic radical A has multiple points of attachments for the NR¹R² group, as indicated by a “p” value greater than 1.

TABLE 1
AMINE-SUBSTITUTED POLYMERIC MATERIALS HAVING
STRUCTURE I

| Example | R¹ | R² | A | p |
|---|---|---|---|---|
| I-1 | H | H | 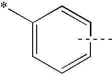 | 1 |
| I-2 | H | Me | 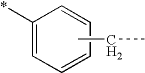 | 1 |
| I-3 | Me | Me | 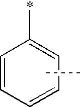 | 1 |
| I-4 | n-butyl | n-butyl | 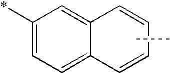 | 1 |
| I-5 | i-propyl | i-propyl | 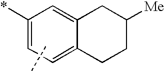 | 1 |
| I-6 | Cyclohexyl | Cyclohexyl | 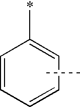 | 1 |
| I-7 | Phenyl | Phenyl | 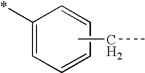 | 1 |
| I-8 | Tolyl | Tolyl | 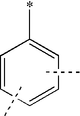 | 2 |
| I-9 | Me | Me | 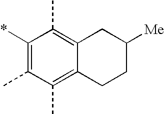 | 3 |
| I-10 | Ethyl | Ethyl | 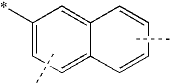 | 2 |

Polystyrene-based amine-substituted intermediate layers are generally beneficial because they are relatively easy to prepare. Thus, in an embodiment, the polymeric materials used may include repeat units having a general structure (III).

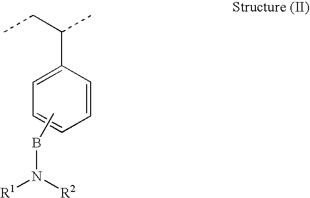

The B in structure (II) may be a single bond or a spacer group, or combinations thereof; and R¹ and R² comprise independently of each other hydrogen atoms, C₁-C₃₀ aliphatic radicals, C₃-C₃₀ cycloaliphatic radicals, C₃-C₃₀ aromatic radicals, or any combination thereof. The spacer groups are exemplified by aliphatic groups, aromatic groups, and combinations having aliphatic and aromatic groups, and the like. The spacer group can also be aliphatic, cycloaliphatic, or aromatic groups, and so on. In an embodiment, the spacer groups may also include heteroatoms, such as oxygen, sulfur, nitrogen, or phosphorus atoms. Examples of spacer groups include C₁ to C₁₂ aliphatic groups, such as methylene, ethylene, propylene, butylene, methyleneoxy, ethyleneoxy, propyleneoxy, cyclohexyleneoxy, C₁ to C₁₂ cycloaliphatic groups, such as cyclohexylene, and cyclohexylidene; and the like.

Polystyrene-based intermediate layers, wherein B is a methylene group, are desirable because they generally can be easily prepared. For example, poly(4-chloromethyl)styrene that is commercially available can be reacted with an amine-based nucleophile, such as NHR¹R² or (NR¹R²)⁻ M⁺, wherein R¹ and R² are as described previously, and M⁺ is a metal cation. Non-limiting examples of metal “M” includes alkali metals such as lithium, sodium, and potassium. Displacement of the chlorine group in the chloromethyl group results in formation of polymeric materials having structure (II). Since a wide variety of amine nucleophiles can be used, a large class of amine-substituted polymeric compounds suitable as functional organic materials for producing the intermediate layers and electronic devices can be prepared. In an embodiment, a suitable amine-substituted polymeric material is at least one of poly[(N,N-dibutylaminomethyl)styrene], poly[(N,N-dimethylaminomethyl)styrene], poly[(N,N-dipropylaminomethyl)styrene], poly[(N,N-ethylmethylaminomethyl)styrene], or poly[(N,N-diethylaminomethyl)styrene]. In another embodiment, intermediate layer comprising the amine-substituted polystyrenes, in combination with a conductive layer, such as those comprising indium tin oxide are particularly useful for producing transparent electronic devices.

In other embodiments, the intermediate layers having at least one amine substituent include structural units derived from at least one polymerizable monomer. Exemplary polymerizable monomers include, but are not limited to vinyl monomers having carbocyclic groups that have at least one amine substituent, or heterocyclic groups that may or may not contain other organic groups possessing at least one amine substituent. Non-limiting examples of suitable vinyl monomers include vinyl naphthalene, styrene, vinyl anthracene, vinyl pentacene, (1,4-diethynyl)aromatics such as (1,4-diethynyl)benzene, and vinyl chrysene that are substituted with amine substituents; and vinyl carbazole, vinyl quinoline, vinyl bipyridyl, vinyl thiophene, and vinyl pyridine, and so forth. Combinations of the foregoing polymerizable vinyl monomers may also be used. Further, the polymerizable monomer may include one or more crosslinkable groups, such as, for example, vinyl groups, allyl groups, styryl groups, and alkynyl groups, each of which may further include at least one amine substituent.

The intermediate layers described above may be used to produce electronic devices. The transparent intermediate layer has an optical band-gap at least of 3.5 eV, as measured with an Ultro-violet and visible absorption technique. The term “transparent” means allowing at least 50 percent, commonly at least 80 percent, and more commonly at least 90 percent, of light in the visible wavelength range. transmitted through a device having a thickness of about 0.5 micrometer, at an incident angle of less than or equal to 10 degrees. In an embodiment of the present invention, a coating composition having at least one amine-substituted polymeric material, at least one amine-substituted non-polymeric material, or inorganic material, or combinations thereof, and at least one solvent is applied as a coating on an electrode surface using techniques known in the art. Polar solvents are generally beneficial because they typically dissolve the aforementioned materials. Non-limiting examples of polar solvents include aliphatic alcohols, such as methanol, ethanol, n-propanol, isopropanol, n-butanol, isobutanol, n-pentanol, and the like. The electrode thus made may further comprise layers that are better able to transfer charge, thereby potentially increasing the efficiency of the device containing the electrode. In an embodiment, the electrode thus obtained can be used in producing electronic devices, such as for example, EL devices, photovoltaic (PV) devices, sensors, electrochromic devices, and field effect transistors, a color-tunable illumination source, which can be formed by a combination of an electro-active material layer and an electrochromic device or any combination thereof and so on.

The state-of-the-art transparent electrode typically consists of a conductive layer made of Indium-Tin Oxide (ITO) because of its superior optical transparency and good electrical conductivity. The ITO layer is usually deposited via sputtering. During the ITO sputtering process, active organic layers are subject to energetic particle bombardment. A buffer layer is usually employed to reduce the likelihood of damage incurred during the ITO sputtering process. Two types of buffer materials have been reported to date, including a thin metal layer (such as Mg:Ag reported by G. Gu et al: “Transparent organic light-emitting devices”, Appl. Phys. Lett. 68, 2606 (1996) and by P.E. Burrows et al “Semitransparent cathodes for organic light-emitting devices”, J. Appl. Phys. 87, 3080 (2000)]) and a thin layer of organic semiconductor such as copper phthalocyanine (CuPc) reported by G. Parthasarathy et al “A metal-free cathode for organic semiconductor devices”, Appl. Phys. Lett. 72, 2138 (1998)]. The intermediate layers disclosed herein generally protect the electro-active organic layers from damage and yield devices with enhanced performance. In one non-limiting example, an electronic display device may be prepared using the intermediate layers described herein. In one embodiment, the intermediate layer may be incorporated into an electronic device to enhance the electron transport from or to an electrode. For example, an organic electroluminescent (“EL”) device can benefit from an intermediate layer of the present invention, such as one of the materials disclosed above, which material is disposed between the conductive layer and the organic electroluminescent layer of the device, such that the material is on the surface of and in contact with the conductive layer. The electro-active organic layer emits light when a voltage is applied across the conductive layers. The intermediate layer may form a distinct interface with the electro-active organic layer, or a continuous transition region having a composition changing from a substantially pure intermediate layer to a substantially pure electro-active organic layer. In an embodiment, the intermediate layer can be deposited on an underlying layer, such as a conductive layer, by a method including spin coating, spray coating, dip coating, roller coating, ink-jet printing, gravure coating techniques, physical vapor deposition, and the like.

The transparent first conductive layer of an organic EL device may be the anode and may generally include a material having a bulk conductivity of at least 100 siemens per centimeter, as measured by a four-point probe technique. Indium tin oxide (ITO) is typically used for this purpose because it is substantially transparent to light transmission and thus facilitates light emitted from electro-active organic layer to escape through the ITO anode layer without being significantly attenuated. The term “transparent” means allowing at least 50 percent, commonly at least 80 percent, and more commonly at least 90 percent, of light in the visible wavelength range transmitted through a device, at an incident angle of less than or equal to 10 degrees. Other materials utilized as the anode layer may include tin oxide, indium oxide, zinc oxide, indium zinc oxide, zinc indium tin oxide, antimony oxide, and mixtures thereof.

In construction, the conductive layer may be deposited on the underlying element by physical vapor deposition, chemical vapor deposition, or sputtering, and other processes. The thickness of conductive layer are generally in the range from about 10 nanometers to about 500 nanometers in an embodiment, from about 10 nanometers to about 200 nanometers in another embodiment, and from about 50 nanometers to about 200 nanometers in still another embodiment. A thin, substantially transparent layer of a metal, for example, having a thickness of less than about 50 nanometers, can also be used as a suitable conductive layer. Such exemplary metals include silver, copper, tungsten, nickel, cobalt, iron, selenium, germanium, gold, platinum, aluminum, or mixtures thereof or alloys thereof. In one embodiment, the anode is disposed on a substantially transparent substrate, such as one constructed of glass or a polymeric material.

In general, the second conductive layer may be the cathode and it serves the purpose of injecting negative charge carriers (electrons) into the electro-active organic layer. In an embodiment, the second conductive layer comprises metals, such as K, Li, Na, Cs, Mg, Ca, Sr, Ba, Al, Ag, Au, In, Sn, Zn, Zr, Sc, Y, elements of the lanthanide series, alloys thereof, or mixtures thereof. Suitable alloy materials for the manufacture of second conductive layer are Ag—Mg, Al—Li, In—Mg, and Al—Ca, Al—Au alloys. Layered non-alloy structures are also feasible, such as a thin layer of a metal such as calcium, or a non-metal, such as LiF, covered by a thicker layer of some other metal, such as aluminum or silver. The second conductive layer may be deposited on the underlying element by physical vapor deposition, chemical vapor deposition, or sputtering.

Further, the electro-active organic layer may serve as the transport medium for both holes and electrons. In this electro-active organic layer, the excited species may combine and drop to a lower energy level, concurrently emitting EM radiation in the visible range. Electro-active organic materials are typically chosen to electroluminesce in the desired wavelength range.

The thickness of the electro-active layer is generally maintained in the exemplary range of about 10 nanometers to about 300 nanometers. The electro-active material may be an organic material, such as a polymer, a copolymer, a mixture of polymers, or lower molecular-weight organic molecules having unsaturated bonds, and so on. Such materials generally possess a delocalized π-electron system, which typically enables the polymer chains or organic molecules to support positive and negative charge carriers with relatively high mobility. Common electro-active polymers are: poly(n-vinylcarbazole) (“PVK”, emitting violet-to-blue light in the wavelengths of about 380-500 nanometers) and its derivatives; polyfluorene and its derivatives such as poly(alkylfluorene), for example poly(9,9-dihexylfluorene) (410-550 nanometers), poly(dioctylfluorene) (wavelength at peak EL emission of 436 nanometers) or poly{9,9-bis(3,6-dioxaheptyl)-fluorene-2,7-diyl} (400-550 nanometers); poly(paraphenylene) (“PPP”) and its derivatives such as poly(2-decyloxy-1,4-phenylene) (400-550 nanometers) or poly(2,5-diheptyl-1,4-phenylene); poly(p-phenylene vinylene) (“PPV”) and its derivatives such as dialkoxy-substituted PPV and cyano-substituted PPV; polythiophene and its derivatives such as poly(3-alkylthiophene), poly(4,4′-dialkyl-2,2′-bithiophene), poly(2,5-thienylene vinylene); poly(pyridine vinylene) and its derivatives; polyquinoxaline and its derivatives; and polyquinoline and its derivatives. Mixtures of these polymers or copolymers may be based on one or more of these polymers and others that may be used to tune the color of emitted light, for example.

Another class of exemplary electro-active materials is polysilanes. Polysilanes are linear silicon-backbone polymers substituted with a variety of alkyl and/or aryl side groups. They are quasi one-dimensional materials with delocalized sigma—conjugated electrons along polymer backbone chains. Examples of polysilanes are poly(di-n-butylsilane), poly(di-n-pentylsilane), poly(di-n-hexylsilane), poly(methylphenylsilane), and poly{bis(p-butylphenyl)silane}, and the like. These polysilanes generally emit light having wavelengths in the range from about 320 nanometers to about 420 nanometers.

Organic materials having molecular weight less than, for example, about 5000 that are made of a large number of aromatic units are also applicable as electro-active materials. An example of such materials is 1,3,5-tris{n-(4-diphenylaminophenyl) phenylamino}benzene, which emits light in the wavelength range of 380-500 nanometers. The electro-active organic layer also may be prepared from lower molecular weight organic molecules, such as phenylanthracene, tetraarylethene, coumarin, rubrene, tetraphenylbutadiene, anthracene, perylene, coronene, or their derivatives. These materials generally emit light having maximum wavelength of about 520 nanometers. Still other advantageous materials are the low molecular-weight metal organic complexes such as aluminum-, gallium-, and indium-acetylacetonate, which emit light in the wavelength range of 415-457 nanometers, aluminum-(picolymethylketone)-bis{2,6-di(t-butyl)phenoxide} or scandium-(4-methoxy-picolylmethylketone)-bis(acetylacetonate), which emits in the range of 420-433 nanometers. For white light application, beneficial electro-active organic materials are those that emit light in the blue-green wavelengths, for example.

Other electro-active organic materials that emit in the visible wavelength range and that may be employed with the present technique are organometallic complexes of 8-hydroxyquinoline, such as tris(8-quinolinolato)aluminum and other materials disclosed in U. Mitschke and P. Bauerle, “The Electroluminescence of Organic Materials,”J. Mater. Chem., Vol. 10, pp. 1471-1507 (2000), which is incorporated herein by reference. Additional exemplary organic materials that may be employed in the EL layer of the present invention include those disclosed by Akcelrud in “Electroluminescent Polymers”, Progress in Polymer Science, Vol 28 (2003), pp. 875-962, which is also incorporated herein by reference. These materials may include polymeric materials whose structures comprise various combinations of structures or structural units that are known in the art to be, or expected to be, electro-active, together with structures that are either known or are potentially expected to perform other functions that enhance device performance, such as hole transport, electron transport, charge transport, and charge confinement, and so forth.

It should be noted that more than one electro-active organic layer may be formed successively, one on top of another. Each layer may have a different electro-active organic material that emits in a different wavelength range.

Furthermore, one or more additional layers may be included in the light-emitting device to further increase the efficiency of the exemplary EL device. For example, an additional layer can serve to improve the injection and/or transport of positive charges (holes) into the EL layer. The thickness of each of these layers is typically kept below 500 nanometers, commonly below 100 nanometers. Exemplary materials for these additional layers are low-to-intermediate molecular weight (for example, less than about 2000) organic molecules, poly(3,4-ethylenedioxythipohene) doped with polystyrenesulfonic acid (“PEDOT:PSS”), and polyaniline, to name a few. They may be applied during the manufacture of the device by conventional methods such as spray coating, dip coating, or physical or chemical vapor deposition, and other processes. In one embodiment of the present invention, a hole injection enhancement layer is introduced between the anode layer and the EL layer to provide a higher injected current at a given forward bias and/or a higher maximum current before the failure of the device. Thus, the hole injection enhancement layer facilitates the injection of holes from the anode. Exemplary materials for the hole injection enhancement layer are arylene-based compounds, such as those disclosed in U.S. Pat. No. 5,998,803, which is incorporated herein by reference. Particular examples include 3,4,9,10-perylenetetra-carboxylic dianhydride and bis(1,2,5-thiadiazolo)-p-quinobis(1,3-dithiole).

The exemplary EL device may further include a hole transport layer disposed between the hole injection enhancement layer and the EL layer. The hole transport layer transports holes and blocks the transportation of electrons so that holes and electrons are substantially optimally combined in the EL layer. Exemplary materials for the hole transport layer may include triaryldiamine, tetraphenyldiamine, aromatic tertiary amines, hydrazone derivatives, carbazole derivatives, triazole derivatives, imidazole derivatives, oxadiazole derivatives having an amino group, and polythiophenes, to name a few.

In other embodiments, the exemplary EL device may further include an “electron injecting and transporting enhancement layer” as an additional layer, which can be disposed between the electron-donating material and the EL layer. Typical materials utilized for the electron injecting and transporting enhancement layer may include metal organic complexes, such as tris(8-quinolinolato)aluminum, oxadiazole derivatives, perylene derivatives, pyridine derivatives, pyrimidine derivatives, quinoline derivatives, quinoxaline derivatives, diphenylquinone derivatives, and nitro-substituted fluorene derivatives, and so on.

In an embodiment, the electro-active material may also be co-mingled with a polymeric material that can serve as a matrix polymer. Generally, any of the known polymeric materials may be used.

The electro-active material may further include at least one of a fluorescent dye or a phosphorescent dye. The light-emitting device can further comprise one or more photoluminescent (“PL”) layers, having at least a fluorescent layer and/or a phosphorescent layer, such as, for example those disclosed in U.S. Pat. No. 6, 847,162.

The intermediate layers produced as described earlier in this disclosure are valuable for forming electronic devices, such as an organic photovoltaic device, a photodetector, a display device, and an organic light emitting device. Display devices are exemplified by devices used for producing signage. Thus in an embodiment, the intermediate layers are useful for making devices comprising a display unit, wherein the display unit comprises a plurality of electronic devices. These electronic devices generally include a first conductive layer, a second conductive layer, an intermediate layer and an electro-active material layer. In an embodiment, at least one of the first or second conductive layers may be transparent. In another embodiment, all the layers present in the electronic devices are transparent. By a transparent electrode is meant an electrode having a percent light transmission of greater than or equal to about 90 percent in an embodiment, and greater than or equal to 95 percent in another embodiment. Another type of electronic devices that can benefit from an efficient transport of electrons across an interface between an electrode and an adjacent EL-active material, are photovoltaic (“PV”) cells.

Still another embodiment of the present invention encompasses a method for operating an electronic device. The method includes applying an electrical field or light energy to the electronic device to convert between electrical energy and light energy. In this exemplary method, the electronic device has a first conductive layer, a second conductive layer, an intermediate layer and an electro-active material layer.

### EXAMPLES

In the following examples, poly(3,4-ethylenedioxythiophene) doped with polystyrene sulfonate (PEDOT:PSS) was purchased from Bayer Corporation under the trade name Baytron® P. A green light-emitting polymer (LEP) was obatined from Dow Chemical Company under the trade name of Lumation® 1304. Poly((N,N-ethylmethylaminomethyl)styrene) (PS-Amine) was synthesized as follows: A solution of an isomeric mixture of poly(3-chloromethyl)styrene and poly(4-chloromethylstyrene) (2 grams, 13.2 millimoles) and N-ethylmethylamine (CAS No. 624-78-2, 11.8 grams, 200 millimoles) in 25 milliliters of toluene was stirred at room temperature for 5 days. The reaction mixture, which was a slurry containing precipitated solids was transferred to a separatory funnel and diluted with toluene. The organic phase was washed twice with 1 weight percent aqueous NaOH solution, twice with water, and the solvent was removed under vacuum. The tacky, white solid residue was dissolved in methanol and precipitated into water in a blender. The collected solid was air-dried, and then dried in a vacuum oven at 50° C. to afford the product poly((N,N-ethylmethylaminomethyl)styrene). Sodium fluoride (≧99%) was purchased from Aldrich and used as received. All Indium Tin Oxide (ITO) coatings were deposited using a CVC601 sputter tool at a base pressure of 1×10⁻⁶ Torr. The ITO DC magnetron sputtering was carried out at pressure of 0.7 mm Torr, with 30 standard cubic centimeter (sccm) of argon (Ar) and 8.5 sccm of O₂. The sputter power density was 18.3 Watts per square inch. The samples were electrically grounded, unheated, and placed 1 inch away from sputter target. To achieve uniform ITO coatings, the substrates were kept constantly rotating (4 seconds per cycle) throughout the deposition process. In the following experiments, the thickness of the sputtered ITO layers was 110 nm; the ITO was deposited in 11 mins, corresponding to a deposition rate of ca 1.7 Angstrom per second. As deposited, the ITO coatings exhibited a sheet resistance around 45 Ohm per square. Optical transmittances were measured with an Ocean Optics USB2000 Miniature Fiber Optic Spectrometer. The device performance was characterized by measuring current-voltage-luminance (I-V-L) characteristics and electroluminescence spectra. A photodiode calibrated with a luminance meter (Minolta LS-110) was used to measure the luminance (in units of candela per square meter, cd/m2). A plot of efficiency (measured in candela per ampere, cd/A) as a function of current density (measured in milliamperes per square centimeter, mA/cm²) was obtained for each device from its I-V-L data.

### Comparative Example 1

### Preparation of a Transparent Electrode Consisting of a 100 nm ITO Layer

The ITO electrode was fabricated as follows. A quartz substrate was cleaned with acetone and isoproponal prior to use. Then a 110 nm ITO layer was sputtered atop of the substrate. Table 1 summarizes the transmittances of the ITO layer at different wavelengths.

### Example 1

### Preparation of a Transparent Electrode Consisting of a PS-Amine/ITO Bilayer

The PS-Amine/ITO bilayer electrode was fabricated as follows. A quartz substrate was cleaned with acetone and isoproponal prior to use. A layer of PS-amine was spin-coated in air atop the LEP from its 1-butanol solution and then baked at 90° C. for 30 mins. The layer of PS-amine had a thickness of about 5 to 8 nm, as determined by both mechanical and optical profilometry. Then a 110 nm ITO layer was sputtered atop the PS-Amine layer. Optical transmittances of the PS-Amine/ITO bilayer electrode at different wavelengths are summarized in Table 1.

### Example 2

### Prepration of a Transparent Electrode Consisting of a Naf/ITO Bilayer

The NaF/ITO bilayer electrode was fabricated as follows. A quartz subsrate was cleaned with acetone and isoproponal prior to use. Then the substrate was transferred to an argon filled glovebox nominally containing less than 1 part per million of moisture and oxygen. Next a 4 nm sodium fluoride layer was thermally evaporated on top of the quartz substrate at a base pressure of 2×10⁻⁶ Torr. The sample was briefly exposed to ambient conditions (24° C., 42% relative humidity) before it was transferred into the ITO deposition chamber. Care was taken to minimize the time of exposure to air. Then a 110 nm ITO layer was sputtered atop the NaF layer. Optical transmittances of the NaF/ITO bilayer are summarized in Table 1.

TABLE 1
Optical Transmittance Of The Transparent Electrodes At Different
Wavelengths

| | Optical transmittance (%) | | |
|---|---|---|---|
| | Comparative | | |
| Wavelength (nm) | Example 1 | Example 1 | Example 2 |
| 350 | 45.55 | 45.47 | 45.33 |
| 400 | 80.81 | 80.89 | 80.34 |
| 450 | 95.22 | 95.13 | 94.60 |
| 500 | 93.87 | 93.79 | 93.61 |
| 550 | 90.04 | 90.07 | 90.24 |
| 600 | 86.73 | 86.71 | 86.58 |
| 700 | 83.72 | 83.76 | 83.89 |
| 800 | 83.36 | 83.37 | 82.03 |

Comparative Example 2: Prepration Of A Transparent OLED With A Bare ITO Electrode As The Cathode

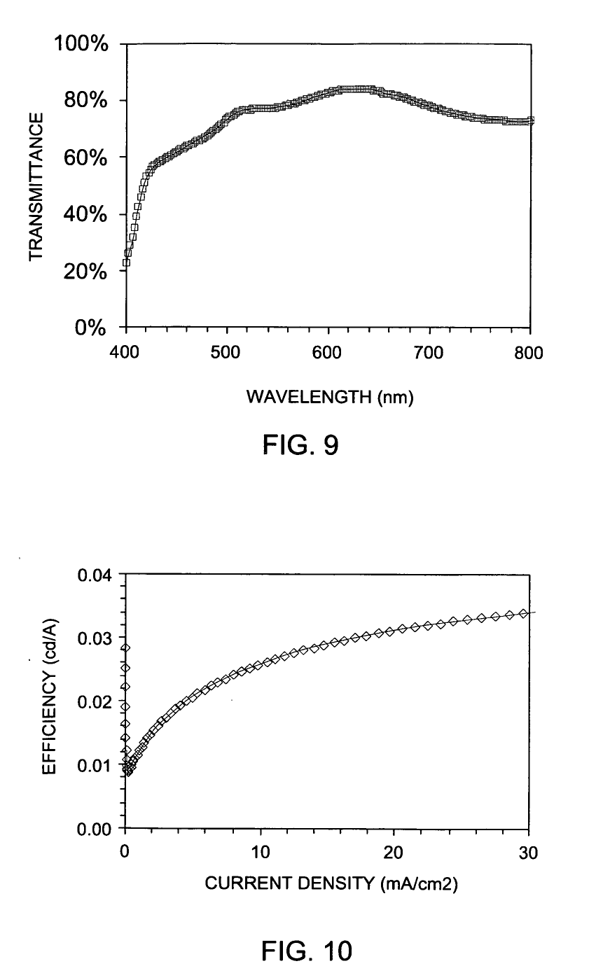

The transparent OLED with a bare ITO cathode was fabricated as follows. glass precoated with ITO was used as the substrate. A 60 nanometer (nm) layer of PEDOT:PSS was deposited onto ultraviolet-ozone treated ITO substrates via spin-coating and then baked for 1 hour at 180° C. in air. A layer of a green LEP (Lumation® 1304) was then spin-coated in air atop the PEDOT:PSS layer under ambient conditions. The LEP layer had a thickness of 65 nm, as determined by mechanical profilometry. Next a 110 nm ITO electrode was applied, as described in Example 1, on top of the LEP. It is stressed that in this example, no PS-Amine intermediate layer is disposed between the LEP and the ITO layer. FIG. 9 shows that the device of comparative example 2 is substantially transparent to radiation having wavelength between 400 and 800 nanometers. FIG. 10 shows that the device of comparative example 2 shows poor efficiency in converting electrical energy into light energy.

### Example 3

### Preparation of a Transparent OLED with a PS-Amine/ITO Bilayer as the Cathode

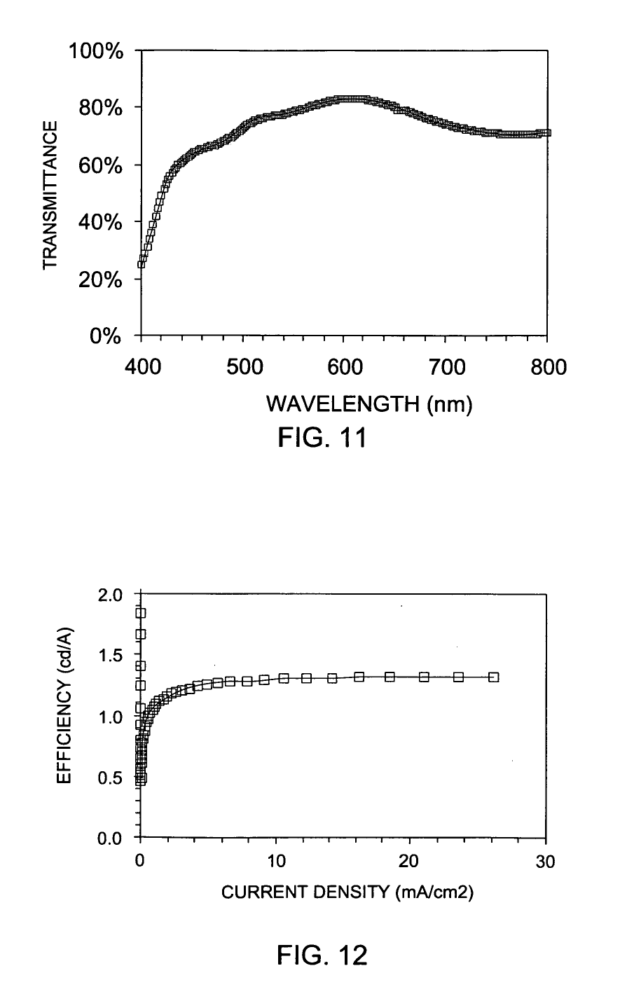

The transparent OLED with a PS-Amine/ITO bilayer cathode was fabricated as follows. Glass pre-coated with ITO was used as the substrate. A 60 nanometer (nm) layer of PEDOT:PSS was deposited onto ultraviolet-ozone treated ITO substrates via spin-coating and then baked for 1 hour at 180° C. in air. A layer of a green LEP (Lumation® 1304) was then spin-coated in air atop the PEDOT:PSS layer under ambient conditions (24° C., 42% relative humidity). The LEP layer had a thickness of 80 nm, as determined by mechanical profilometry. Next a PS-Amine/ITO bilayer electrode was applied, as described in Example 1, on top of the LEP. FIG. 11 shows that the device of example 3 is substantially transparent to radiation having wavelength between 400 and 800 nanometers. FIG. 12 shows that the device of example 3 shows better efficiency in converting electrical energy into light energy relative to the device of comparative example 2.

### Example 4

### Preparation of a Transparent OLED with a Naf/ITO Bilayer Cathode

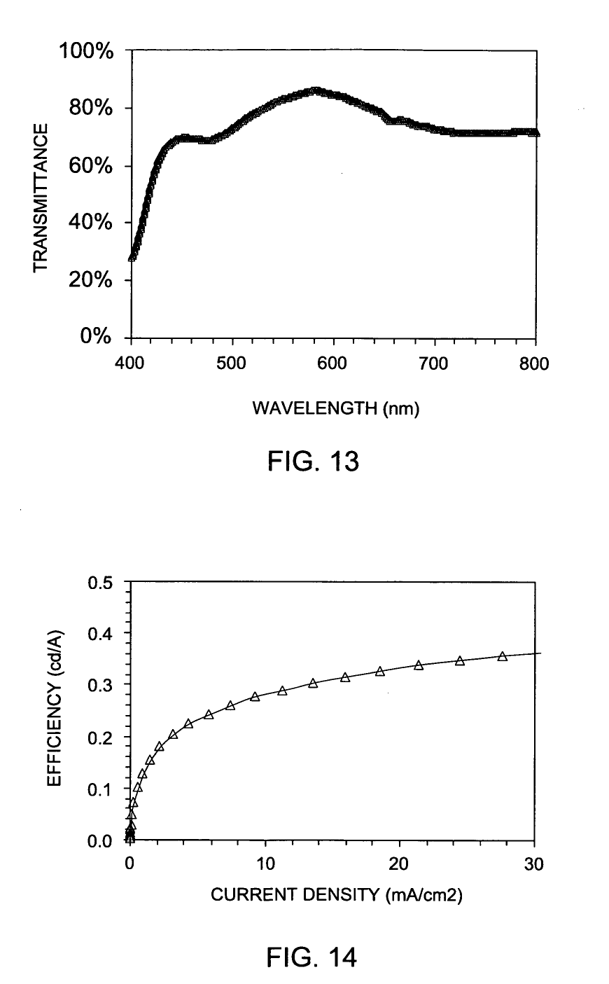

The transparent OLED with a NaF/ITO was fabricated as follows. Glass pre-coated with ITO was used as the substrate. A 60 nm layer of PEDOT:PSS was deposited onto ultraviolet-ozone treated ITO substrates via spin-coating and then baked for 1 hour at 180° C. in air under ambient conditions (24° C., relative humidity 35%). A layer of a green LEP (Lumation® 1304) was then spin-coated in air atop the PEDOT:PSS layer. The LEP layer had a thickness of 70 nm, as determined by mechanical profilometry. Then the sample was moved into an argon filled glovebox nominally containing less than 1 part per million of moisture and oxygen. Next a NaF(4 nm)/ITO(110 nm) bilayer electrode was applied, as described in Example 2, atop of the LEP. FIG. 13 shows that the device of example 4 is substantially transparent to radiation having wavelength between 400 and 800 nanometers. FIG. 14 shows that the device of example 4 shows better efficiency in converting electrical energy into light energy relative to the device of comparative example 2.

The use of PS-Amine (Examples 1 and 3) and NaF (Examples 2 and 4) did not affect the optical performance in that the bilayer electrodes as well as the OLEDs with the bilayer electrodes as the cathode exhibit comparable transmittance relative to the devices of comparative examples 1 and 2 with a bare ITO layer. The use of PS-Amine (Example 3) and NaF (Example 4) yielded transparent OLEDs with significantly enhanced efficiency relative to the device of comparative example 2 without either PS-Amine or NaF.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A transparent electrode comprising:
(a) at least one optically transparent electrically conductive layer; and
(b) at least one optically transparent intermediate layer having a thickness of from about 1 and about 100 angstroms;
wherein said optically transparent electrically conductive layer is in contact with said optically transparent intermediate layer, said optically transparent conductive layer having a conductivity at least 100 Siemens per centimeter (S/cm), said optically transparent intermediate layer being comprised of a material having a bulk electrical conductivity at room temperature of less than about 10⁻¹² Siemens per centimeter (S/cm), and a band gap of at least 3.5 eV.

2. The transparent electrode according to claim 1, wherein said transparent electrically conductive layer comprises at least one metal oxide.

3. The transparent electrode according to claim 2, wherein said metal oxide is selected from the group consisting of indium tin oxide, tin oxide, indium oxide, zinc oxide, indium zinc oxide, zinc indium tin oxide, antimony oxide, and mixtures thereof.

4. The transparent electrode according to claim 1, wherein said transparent electrically conductive layer comprises at least one zero valent metal.

5. The transparent electrode according to claim 4, wherein said zero valent metal is selected from the group consisting of magnesium, calcium, barium, copper, silver, gold, aluminum, mercury, nickel, platinum, and mixtures thereof.

6. The transparent electrode according to claim 1, wherein said transparent electrically conductive layer comprises indium tin oxide.

7. The transparent electrode according to claim 1, wherein said intermediate layer is an organic material.

8. The transparent electrode according to claim 1, wherein said intermediate layer is an inorganic material.

9. The transparent electrode according to claim 1, wherein said intermediate layer comprises at least one organic component and at least one inorganic component.

10. The transparent electrode according to claim 1, wherein said intermediate layer comprises an amine-substituted polymeric material comprising repeat units having structure (I): 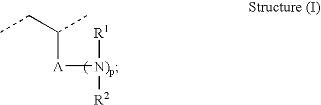
wherein A is an aromatic radical, R¹ and R² are independently a hydrogen , a C₁-C₃₀ aliphatic radical, a C₃-C₃₀ cycloaliphatic radical, or a C₃-C₃₀ aromatic radical; and “p” is an integer from 1 to the maximum number of positions available for substitution on A.

11. The transparent electrode according to claim 10, wherein A is selected from the group consisting of phenylene, naphthylene, anthracenylene, and fluorenylene.

12. The transparent electrode according to claim 10, wherein the amine-substituted polymeric material comprises at least one of a dialkylamino group, a monoalkylamino group, or a NH₂ group.

13. The transparent electrode according to claim 10, wherein the amine-substituted polymeric material is selected from the group consisting of poly[(N,N-dibutylaminomethyl)styrene], poly[(N,N-dimethylaminomethyl)styrene], poly[(N,N-dipropylaminomethyl)styrene], poly[(N,N-ethylmethylaminomethyl)styrene], poly[(N,N-diethylaminomethyl)styrene], and mixtures of two or more of the foregoing.

14. The transparent electrode according to claim 1, wherein the intermediate layer comprises at least one intermediate material selected from the group consistng of calcium oxide, barium oxide, sodium oxide, and combinations thereof.

15. The transparent electrode according to claim 1, wherein the optically transparent intermediate layer comprises at least one intermediate material selected from the group consistng of sodium fluoride, lithium fluoride, potassium fluoride, cesium fluoride, calcium fluoride, barium fluoride, sodium chloride, and combinations thereof.

16. The transparent electrode according to claim 1, wherein the intermediate layer has a thickness in the range of from about 5 angstroms to about 100 angstroms.

17. The transparent electrode according to claim 1, wherein the intermediate layer has a thickness in the range of from about 15 angstroms to about 100 angstroms.

18. The transparent electrode according to claim 1, wherein the intermediate layer has a thickness in the range of from about 25 angstroms to about 50 anngstroms.

19. A light emitting device comprising a transparent electrode of claim 1.

20. A light emitting device comprising:
(a) at least one optically transparent electrically conductive layer
(b) at least one optically transparent intermediate layer having a thickness of from about 1 and about 100 angstroms; and
(c) at least one electro-active organic layer
wherein said optically transparent electrically conductive layer is in contact with said optically transparent intermediate layer, said optically transparent conductive layer having a conductivity at least 100 Siemens per centimeter (S/cm), said optically transparent intermediate layer being comprised of a material having a bulk electrical conductivity at room temperature of less than about 10⁻¹² Siemens per centimeter (S/cm), and a band gap of at least 3.5 eV.

21. The light emitting device according to claim 20, wherein said transparent electrically conductive layer comprises at least one metal oxide.

22. The light emitting device according to claim 20, wherein said transparent electrically conductive layer comprises at least one zero valent metal.

23. The light emitting device according to claim 20, wherein said intermediate layer comprises an amine-substituted polymeric material comprising structural units (I): 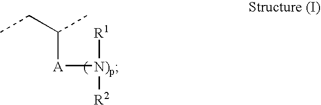
wherein A is an aromatic radical, R^{1 and R}² are independently a hydrogen , a C₁-C₃₀ aliphatic radical, a C₃-C₃₀ cycloaliphatic radical, or a C₃-C₃₀ aromatic radical; and “p” is an integer from 1 to the maximum number of positions available for substitution on A.

24. A method for fabricating a transparent electronic device, the method comprising:
providing a substrate;
disposing a transparent electrically conducting layer having a conductivity at least 100 Siemens per centimeter (S/cm); and
disposing a transparent intermediate layer having a thickness of from about 1 and about 100 angstroms, a bulk electrical conductivity at room temperature of less than about 10⁻¹² Siemens per centimeter (S/cm), and a band gap of at least 3.5 eV;
wherein the transparent intermediate layer comprises sodium fluoride, calcium oxide, or an amine-substituted polymeric material having a repeat unit as shown in structure (I): 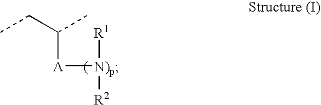
wherein A comprises an aromatic radical, R¹ and R² comprise independently of each other hydrogen atom, C₁-C₃₀ aliphatic radicals, C₃-C₃₀ cycloaliphatic groups, C₃-C₃₀ aromatic radicals, or any combination thereof; and “p” comprises an integer from 1 to the maximum number of positions available for substitution on A; or combinations thereof.

25. The method of claim 24, wherein the substrate comprises metal, coated metal, planarized metal, glass, plastic material, coated plastic material, thermoplastic material, thermoset material, elastomeric material, or combinations thereof.

26. The method of claim 24, wherein said disposing comprises spin casting, drop casting, ink-jet printing, gravure coating techniques, reverse microgravure coating, flexo printing, or any other type of roll coating or roll printing, screen printing, physical vapor deposition, or combinations thereof.
